(19) United States
(12) Patent Application Publication
(10) Pub. No.: US 2007/0183469 A1
(43) Pub. Date: Aug. 9, 2007

(54) Nitride based semiconductor laser diode

(75) Inventor: Han-youl Ryu, Suwon-si (KR)

Correspondence Address: BUCHANAN, INGERSOLL & ROONEY PC, POST OFFICE BOX 1404, ALEXANDRIA, VA, 22313-1404, US

(73) Assignee: SAMSUNG ELECTRONICS CO., LTD., Suwon-si (KR)

(21) Appl. No.: 11/505,874

(22) Filed: Aug. 18, 2006

(30) Foreign Application Priority Data
Feb. 8, 2006 (KR) 10-2006-0012056

(51) Int. Cl. H01S 5/00; H01S 3/04

(52) U.S. Cl. 372/43.01

(57) ABSTRACT

A nitride based semiconductor laser diode is provided. The nitride based semiconductor laser diode includes: a lower contact layer, a lower clad layer, an active layer, and an upper clad layer sequentially stacked on a substrate, wherein the refractive index of the lower clad layer is equal to or greater than the refractive index of the lower contact layer.

### CROSS-REFERENCE TO RELATED PATENT APPLICATION

This application claims the benefit of Korean Patent Application No. 10-2006-0012056, filed on Feb. 8, 2006 in the Korean Intellectual Property Office, the disclosure of which is incorporated herein in its entirety by reference.

### BACKGROUND OF THE DISCLOSURE

1. Field of the Disclosure

The present disclosure relates to a nitride based laser diode, and more particularly, to a nitride based laser diode in which the beam quality of the laser light is improved by suppressing the loss of the optical mode.

2. Description of the Related Art

Semiconductor laser diodes are widely used in communication fields such as optical communication or in compact disk players (CDP) or digital multifunctional disk displayers (DVDP) for data transmission and data recording/reading.

Since nitride based semiconductor laser diodes can emit light with wavelengths from green to ultraviolet, they are employed in various fields such as in the storing and reproducing of high density optical information and in laser printers and projection TVs of high resolution.

Generally nitride based semiconductor laser diodes are formed by stacking an n-type contact layer, an n-type clad layer, an active layer, and a p-type clad layer sequentially on a substrate, and confining the laser light generated from the active layer by the difference between refractive indices to obtain an optical gain.

A portion of the laser light confined in the active layer may leak and head toward the n-type clad layer or the p-type clad layer. In case of a conventional nitride based semiconductor laser diode, the refractive index of the n-type contact layer is generally higher than the refractive index of the n-type clad layer, and thus leakage component of the laser light heading toward the n-type clad layer does not disappear but propagates to the substrate, thereby generating light leakage in an optical mode.

The leakage in the optical mode causes poor beam quality of the laser light by creating a ripple in a far field.

In order to reduce the leakage in the optical mode, the amount of the laser light that leaks to the n-type clad layer should be reduced, or the laser light that leaks to the n-type clad layer should not propagate toward the substrate. For this reason, in a conventional nitride based laser diode, the composition ratio of Al in the n-type clad layer having the composition of AlₓGa₁₋ₓN (0<x<1) is increased to suppress the leakage from the active layer to the n-type clad layer, or the thickness of the n-type clad layer is increased to sufficiently suppress the light that leaks to the n-type clad layer before the light propagates to the substrate. However, when the composition of Al of the n-type clad layer or the thickness of the n-type clad layer is increased, a crack is more likely to occur during the growth of the n-type clad layer.

Also, in the nitride based semiconductor laser diode, the leakage in the optical mode increases as the wavelength of the laser light increases from violet to blue or green, and thus the beam quality is significantly diminished. This can create a serious problem when the nitride based semiconductor laser diode is used as a display light source.

### SUMMARY OF THE DISCLOSURE

The present invention may provide a nitride based semiconductor laser diode in which light leakage in an optical mode toward a substrate is suppressed, thereby improving the beam quality of the laser light.

According to an aspect of the present invention, there may be provided a nitride based semiconductor laser diode comprising: a substrate; a lower contact layer; a lower clad layer; an active layer; and an upper clad layer sequentially stacked on the substrate, wherein the refractive index of the lower clad layer is equal to or greater than the refractive index of the lower contact layer.

According to another aspect of the present invention, there may be provided a nitride based semiconductor laser diode comprising: a substrate; a lower clad layer; an active layer; and an upper clad layer sequentially stacked on the substrate, wherein the refractive index of the lower clad layer is equal to or greater than the refractive index of the substrate.

### BRIEF DESCRIPTION OF THE DRAWINGS

The above and other features and advantages of the present invention are illustrated in detailed exemplary embodiments thereof with reference to the attached drawings in which:

FIG. 1 illustrates a cross-sectional view of a nitride based semiconductor laser diode according to an embodiment of the present invention and the profile of a refractive index thereof;

FIG. 2 is a graph illustrating the optical confinement factor (OCF) of the nitride semiconductor laser diode of FIG. 1 according to the thickness of the lower clad layer;

FIG. 3 illustrates the full width at half maximum (FWHM) of the far field pattern (FFP) of the nitride based semiconductor laser diode of FIG. 1 according to the thickness of the lower clad layer;

FIG. 4 illustrates a cross-sectional view of a nitride based semiconductor laser diode according to another embodiment of the present invention and the profile of the refractive index thereof;

FIGS. 5A through 5C are graphs illustrating experimental results obtained in a conventional nitride based semiconductor laser diode; and

FIGS. 6A and 6B are graphs illustrating experimental results obtained in the nitride semiconductor laser diode manufactured according to the embodiments of the present invention.

### DETAILED DESCRIPTION OF EXEMPLARY EMBODIMENTS

The present invention will now be described with reference to the accompanying drawings, in which exemplary embodiments of the invention are shown.

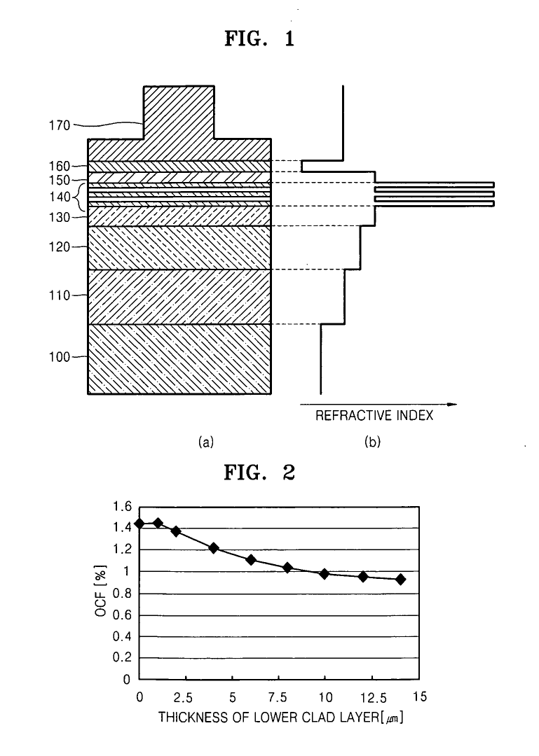

In FIG. 1, (a) is a cross-sectional view of a nitride based semiconductor laser diode according to an embodiment of the present invention, and (b) illustrates the profile of the refractive index of each semiconductor layer constituting the nitride based semiconductor laser diode.

Referring to FIG. 1, the nitride based semiconductor laser diode includes a lower contact layer 110, a lower clad layer 120, a lower light waveguide layer 130, an active layer 140, an upper light waveguide layer 150, an electron blocking layer 160, and an upper clad layer 170, all of which are sequentially stacked on a substrate 100. The lower clad layer 120 has a refractive index equal to or greater than the refractive index of the lower contact layer 110. Though not illustrated in the drawings, a first electrode layer and a second electrode layer may be respectively formed on a lower surface of the substrate 100 and on an upper surface of the upper clad layer 170. The first and second electrode layers may be respectively an n-type electrode layer and a p-type electrode layer.

The substrate 100 may be a sapphire substrate.

The lower contact layer 110 and the lower clad layer 120 are sequentially stacked on the substrate 100.

The lower contact layer 110 may be formed of an n-type AlₓGa₁₋ₓN compound semiconductor, and the average composition ratio of Al thereof may preferably be in the range of 0<x<0.1.

The lower clad layer 120 may be formed of an n-type Al_{y}Ga_{1-y}N compound semiconductor. Generally, in the case of the AlGaN compound semiconductor, as the composition of Al increases, the refractive index of the material decreases. Accordingly, the average composition y of Al of the lower clad layer 120 may be equal to or smaller than the average composition x of Al of the lower contact layer 110 so that the refractive index of the lower clad layer 120 is equal to or greater than the refractive index of the lower contact layer 110. That is, the average composition of Al of the lower contact layer 110 and the lower clad layer 120, may be preferably in the range of O<y<x<O.1. With the above-described composition, the leakage component of light propagated toward the lower clad layer 120 does not propagate in the lower contact layer 110 and light leakage in the optical mode can be suppressed.

Generally, in nitride based semiconductor laser diodes, in order to intensely confine the optical mode, the composition of Al in the clad layer or the thickness of the clad layer must be increased. However, due to crack generation or difficulty in crystal growing, the optical mode is not sufficiently confined and a portion of the optical mode is leaked to the clad layer. Thus, in the present embodiment, the refractive index of the lower clad layer 120 is set to be equal to or greater than the refractive index of the lower contact layer 110 so that the leakage element of the optical mode propagated toward the lower clad layer 120 does not propagate in the lower contact layer 110 but disappears to intensely confine the optical mode. Also, since the clad layer 120 is formed of AlGaN with a low Al composition, the possibility of crack generation can be reduced.

The lower clad layer 120 may also be a multi-layer structure in which n-type Al_{y′}Ga_{1-y′}N layers having different compositions y′ of Al are alternately stacked. For example, the lower clad layer 120 may be formed of repeated Al_{0.08}Ga_{0.92}N/GaN layers. When the lower clad layer 120 is formed of a plurality of layers, the cracks are created less frequently, and thus the lower clad layer 120 can be stably grown.

A lower light waveguide layer 130 is formed on the lower clad layer 120, and the lower light waveguide layer 130 may be formed of n-type InₓGa₁₋ₓN (0≦x≦0.2) compound semiconductor. An active layer 140 is formed on the lower light waveguide layer 130, and the active layer 140 may be formed of InₓGa₁₋ₓN (0<x<1) compound semiconductor. The active layer 140 may have a multiple quantum well structure or a single quantum well structure. An upper light waveguide layer 150 is formed on the active layer 140, and the upper light waveguide layer 150 may be formed of a p-type InₓGa₁₋ₓN (0≦x≦0.2) compound semiconductor. Meanwhile, an electron blocking layer 160 is formed on the upper light waveguide layer 150 to prevent the electrons from overflowing, and the electron blocking layer 160 may be formed of AlₓGa₁₋ₓN (0<x<1) compound semiconductor. An upper clad layer 170 is formed on the electron blocking layer 160, and the upper clad layer 170 is formed of a p-type AlₓGa₁₋ₓN (0<x<1, preferably, 0.01≦x≦0.1) compound semiconductor.

As described above, when the average composition x of Al in the lower contact layer 110 is equal to or greater than the average composition y of Al in the lower clad layer, the lower clad layer 120 has a refractive index equal to or greater than the refractive index of the lower contact layer 110, thereby suppressing the loss of the optical mode of the active layer 140. Thus, the optical mode is effectively confined and the creation of ripple in the far field of the laser light is suppressed and the beam quality of the laser light can be improved.

Furthermore, the thickness of the lower clad layer 120 can be adjusted to adjust the optical confinement factor (OCF) or the far field pattern (FFP) to change the characteristic of the laser light.

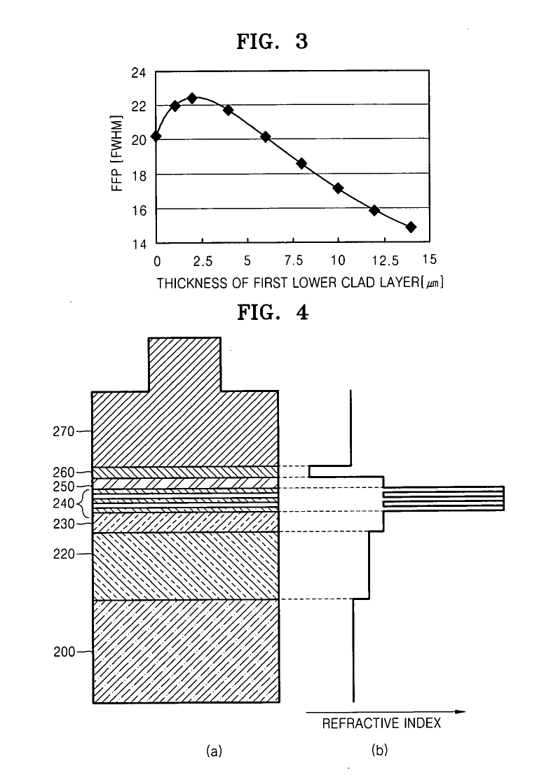

FIG. 2 is a graph illustrating the OCF of the lower clad layer according to the thickness of the lower clad layer, and FIG. 3 is a graph illustrating the FFP of the lower clad layer according to the thickness of the lower clad layer. The data in FIGS. 2 and 3 is measured using a nitride based semiconductor laser diode in which the lower contact layer is formed of n-type Al_{0.01}Ga_{0.99}N, the lower clad layer is formed of n-type GaN, the lower light waveguide layer is formed of n-type In_{0.03}Ga_{0.97}N having a thickness of 600 Å, the active layer is formed of a multiple quantum well structure of _{0.15}Ga_{0.85}N/In_{0.04}Ga_{0.96}N, the upper light waveguide layer is formed of p-type In_{0.03}Ga_{0.97}N having a thickness of 600 Å, and the upper clad layer is formed of p-type Al_{0.02}Ga_{0.98}N having a thickness of 5000 Å.

Referring to FIG. 2, a sufficient OCF for laser light oscillation can be obtained with the lower clad layer formed of n-type GaN.

Also, since the light leakage in the optical mode is suppressed regardless of the thickness of the lower clad layer in the nitride based semiconductor laser diode in the present embodiment, FFP can be adjusted by adjusting the thickness of the lower clad layer as illustrated in FIG. 3.

According to another embodiment of the present invention, the lower clad layer (120 in FIG. 1) can also be formed of n-type In_{y}Ga_{1-y}N. In this case, the average composition of Al in the lower contact layer 110 formed of n-type AlₓGa₁₋ₓN is in the range of 0≦x≦0.1, and the average composition of In is in the range of 0≦y≦0.1. With the above composition ratios, the lower clad layer 120 has a refractive index equal to or greater than the refractive index of the lower contact layer 110, and the optical mode in the active layer 140 mode can be confined more intensely. As a result, the creation of ripple in the far field of the laser light is suppressed, and the beam quality of the nitride based semiconductor laser diode can be improved. The lower clad layer 120 may be a single layer structure, but also may be a multi-layer structure in which n-type In_{y′}Ga_{1-y′}N layers having different composition ratios y′ of In are alternately stacked.

In FIG. 4, (a) is a cross-sectional view of a nitride based semiconductor layer according to another embodiment of the present invention, and (b) illustrates the profile of the refractive index of each semiconductor layer constituting the nitride based semiconductor laser diode.

Referring to FIG. 4, the nitride based semiconductor laser diode in the present embodiment includes a lower clad layer 220, a lower light waveguide layer 230, an active layer 240, an upper light waveguide layer 250, and an upper clad layer 270, all of which are sequentially stacked on a substrate 200. The lower clad layer 210 has a refractive index that is equal to or greater than the refractive index of the substrate 200. Though not illustrated in the drawings, a first electrode layer and a second electrode layer can be formed on a lower surface of the substrate 200 and on an upper surface of the clad layer 270. The first and second electrode layers may be respectively an n-type electrode layer and a p-type electrode layer.

The substrate 200 may be a GaN substrate.

Unlike in the previous embodiment, the lower clad layer 220 is stacked on the substrate 200 without a lower contact layer. A lower light waveguide layer 230, an active layer 240, an upper light waveguide layer 250, an electron blocking layer 260, and an upper clad layer 270 are sequentially stacked on the lower clad layer 220. Since each layer of the present embodiment corresponds to the layers of the previous embodiment, the description thereof is not being repeated.

The lower clad layer 120 can be formed of an n-type In_{y}Ga_{1-y}N compound semiconductor, and the average composition of In may be in the range of 0≦y≦0.1.

With the above composition, the lower clad layer 220 has a refractive index equal to or greater than the refractive index of the substrate 200. Accordingly, the leakage element of light propagated toward the lower clad layer 220 does not propagate in the substrate 200 and disappear, thereby confining the optical mode intensely, and thus the creation of ripple in the far field of the laser light is suppressed and the beam quality can be improved. Also, since the lower clad layer 220 is formed of GaN or InGaN, the temperature for crystal growth can be lowered.

Meanwhile, the lower clad layer 220 may be a single layer structure formed of n-type In_{y}Ga_{1-y}N or a multi layer structure in which a plurality of n-type In_{y′}Ga_{1-y′}N layers having different Al compositions y′ are alternately stacked. The lower clad layer 220 in which a plurality of layers are stacked reduces the possibility of crack generation, thereby facilitating stable crystal growth.

### EXAMPLE

A nitride based semiconductor laser diode according to an embodiment of the present invention is manufactured. Referring to FIG. 1 again, the substrate 100 is a sapphire substrate. The lower contact layer 110 is formed of n-type Al_{0.02}Ga_{0.98}N. The lower clad layer 120 is formed of n-type Al_{0.01}Ga_{0.99}N. The lower light waveguide layer is formed of n-type In_{0.03}Ga_{0.97}N having a thickness of 600 Å. The active layer is formed of a multiple quantum well structure formed of In_{0.15}Ga_{0.85}N/In_{0.04}Ga_{0.96}N. The upper light waveguide layer is formed of p-type In_{0.03}Ga_{0.97}N having a thickness of 600 Å. The upper clad layer is formed of Al_{0.02}Ga_{0.98}N.

### COMPARATIVE EXAMPLE

As a comparative example, a conventional nitride based semiconductor laser diode is manufactured, in which the lower contact layer is formed of n-type GaN and the lower clad layer is formed of Al_{0.15}Ga_{0.85}N and the refractive index of the lower clad layer is smaller than the refractive index of the lower contact layer. The nitride based semiconductor laser diode of the comparative example has the same structure as the nitride based semiconductor laser diode in the example of the present invention except in the lower contact layer and the lower clad layer.

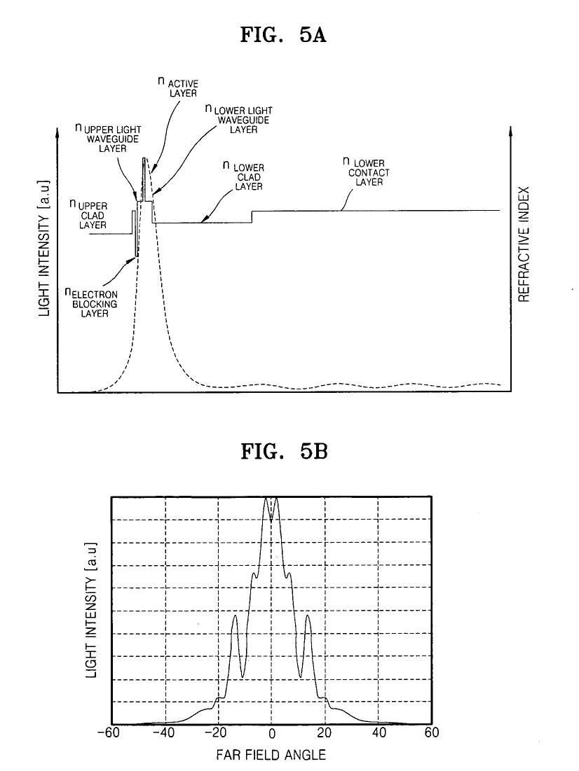

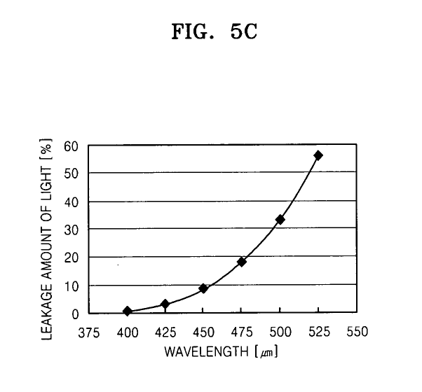

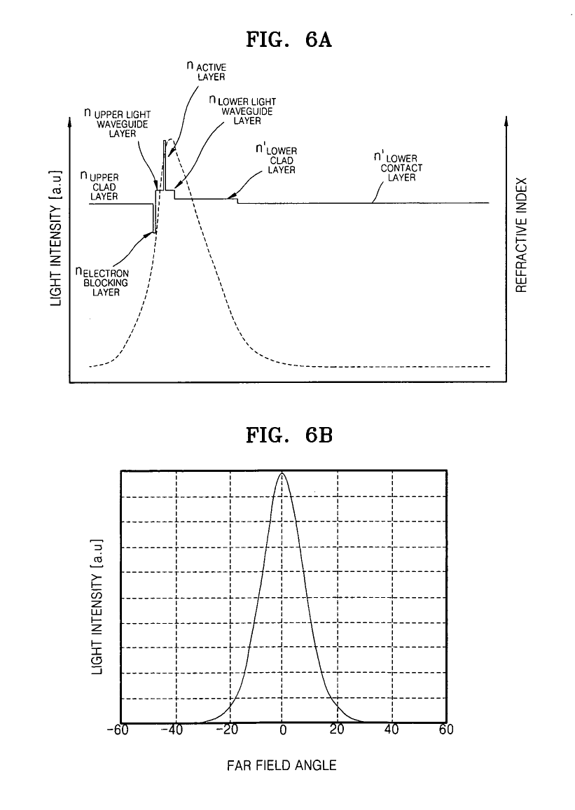

The experimental results for the nitride based semiconductor laser diode according to the present example and the comparative example will now be described with reference to FIGS. 5A and 5B and FIGS. 6A through 6B.

FIG. 5A is a graph illustrating the refractive index and the light intensity of each layer of the nitride based semiconductor laser diode according to the comparative example, and FIG. 5B is a graph illustrating the FFP of the comparative example.

The light intensity is expressed in an arbitrary unit (a.u.). Referring to FIG. 5A, the nitride based semiconductor laser diode in the comparative example has a conventional refractive index distribution where the refractive index of the lower clad layer (n_{lower clad layer}) is smaller than the refractive index of the lower contact layer (n_{lower contact layer}). Accordingly, the leakage of light in the optical mode propagated toward the lower clad layer is propagated toward the lower contact layer and thus the optical confinement is weakened. The light leakage in the optical mode is, as illustrated in FIG. 5B, the factor causing ripple in the far field, and consequently deteriorates the beam quality.

FIG. 5C is a graph illustrating the loss of the optical mode according to the wavelength of the laser light of the nitride based semiconductor laser diode manufactured according to the comparative example. Referring to FIG. 5C, the light leakage in the optical mode increases as the wavelength of the laser light increases from violet to blue or green. Since the light leakage in the optical mode significantly deteriorates the beam quality, it can be a serious problem when the nitride based semiconductor laser diode is used as a display light source which requires light of various wavelengths.

FIG. 6A is a graph illustrating the refractive index and the light intensity of each laser of the nitride based semiconductor laser diode according to the example of the present invention, and FIG. 6B is a graph illustrating the FFP of the nitride based semiconductor laser diode of the present example.

Referring to FIGS. 6A and 6B, as the refractive index of the lower clad layer (n′_{lower clad layer}) is greater than the refractive index of the lower contact layer (n′_{lower contact layer}), the profile of the light intensity shows a smooth curve. This means that the leakage component of light propagated toward the lower clad layer does not propagate in the lower contact layer any more but disappears, and thus the optical mode is intensely confined. Accordingly, as the optical mode is not leaked, a ripple is not created in the far field and the light intensity is distributed in a smooth fashion, and thereby the beam quality of the laser light is excellent.

Furthermore, since the optical mode is not leaked in the present embodiment, the leakage of light in the optical mode according to the wavelength does not increase as in the comparative example, and thus the beam quality of the laser light can be maintained at various wavelengths like violet, blue, or green, particularly, in the long wavelength band.

As described above, the nitride based semiconductor laser diode according to the present invention has the following advantages.

First, the leakage of light in the optical mode toward the substrate is suppressed to improve the beam quality of the laser light.

Second, the OCF or the FFP can be adjusted by adjusting the thickness of the lower clad layer.

Third, leakage of the optical mode can be prevented regardless of the wavelength of the laser light, and thus the beam quality of the laser light can be maintained at various wavelengths, and particularly, the beam quality can be improved at the long wavelength band.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nitride based semiconductor laser diode comprising:
a substrate;
a lower contact layer;
a lower clad layer;
an active layer; and
an upper clad layer sequentially stacked on the substrate,
wherein the refractive index of the lower clad layer is equal to or greater than the refractive index of the lower contact layer.

2. The nitride based semiconductor laser diode of claim 1, wherein the lower contact layer is formed of AlₓGa₁₋ₓN, and the lower clad layer is formed of Al_{y}Ga_{1-y}N, and the average composition of Al is in the range of 0≦y≦x≦0.1.

3. The nitride based semiconductor laser diode of claim 2, wherein the lower clad layer has a single layer structure or a multi layer structure in which layers having different compositions of Al are alternately stacked.

4. The nitride based semiconductor laser diode of claim 1, wherein the lower contact layer is formed of AlₓGa₁₋ₓN, and the lower clad layer is formed of In_{y}Ga_{1-y}N, and the average composition of Al is in the range of 0≦x≦0.1, and the average composition of In is in the range of 0≦y≦0.1.

5. The nitride based semiconductor laser diode of claim 4, wherein the lower clad layer has a single layer structure or a multi layer structure in which layers having different compositions of In are alternately stacked.

6. The nitride based semiconductor laser diode of claim 1, wherein the substrate is a sapphire substrate.

7. A nitride based semiconductor laser diode comprising:
a substrate;
a lower clad layer;
an active layer; and
an upper clad layer sequentially stacked on the substrate,
wherein the refractive index of the lower clad layer is equal to or greater than the refractive index of the substrate.

8. The nitride based semiconductor laser diode of claim 7, wherein the lower clad layer is formed of InₓGa₁₋ₓN, and the average composition of In is in the range of 0≦y≦0.1.

9. The nitride based semiconductor laser diode of claim 8, wherein the lower clad layer has a single layer structure or a multi layer structure in which layers having different composition of In are alternately stacked.

10. The nitride based semiconductor laser diode of claim 7, wherein the substrate is formed of GaN.

11. The nitride based semiconductor laser diode of claim 1, wherein a layer between the active layer and the substrate is formed of an n-type semiconductor, and the upper clad layer is formed of a p-type semiconductor.
